(19) United States
(12) Patent Application Publication
(10) Pub. No.: US 2005/0185377 A1
(43) Pub. Date: Aug. 25, 2005

(54) Computer cooling system

(76) Inventor: Matteo Bonifacio Gravina, Laredo, TX (US)

Correspondence Address: MATTEO B. GRAVINA, 5835 LONGORIA LOOP, LAREDO, TX, 78041, US

(21) Appl. No.: 11/058,687

(22) Filed: Feb. 15, 2005

Related U.S. Application Data
(60) Provisional application No. 60/546,529, filed on Feb. 20, 2004.

(51) Int. Cl. H05K 5/00; H05K 7/20

(52) U.S. Cl. 361/687

(57) ABSTRACT

A thermal transfer energy computer cooling system for air conditioning the air around a computer. A recombinant heat energy extractor for overall components in a computational device. A computer cooling system wherein extracts heat energy created in and around an electrical system by forcing cool air around continuously in an electrical device by complementing of fans, ducts, and other thermal heat extractors in computers.

### CROSS REFERENCE TO RELATED APPLICATIONS

This application claims the benefit of U.S. Provisional Application Ser. No. 60/546,529, filed Feb. 20, 2004 for “COMPUTER COOLING SYSTEM” which is hereby incorporated by reference herein.

### FIELD OF THE INVENTION

This invention relates to computer and computer related systems thermal transfer enclosures, specifically to computer semi encapsulated systems.

### BACKGROUND OF THE INVENTION

With the advent of the computer, specifically the personal computer, lots of sub industries have spun up. The personal computer is the only technology marvel that has grown faster in abilities and capacities. As a global economic environment has contributed to faster and more powerful systems, their power consumption has grown as well. Personal and workstation systems have multiple components that can be added or interchange. This aspect (facet) of interchangeable components have contributed to faster and larger at times systems. As with new technologies coming to market the consumer market as well as business and industry adapt to this modifications. Ever since the first computers that hit the market in the early 1980's computer technology can be measured in its software and hardware compatibility. These measures are akin to this industry and can only change in parallel. The ruler's uses over time are the speed of the microprocessor, in hertz; and the architecture of the operating software-hardware system, in bits.

Over the past twenty years we have seen computers grown so much that consumers expect to add other components to their systems. With software and hardware adapting to its ever changing environment, new components can be added, such as radio, television, audio, video, and multimedia cards. With these features added to the system, its power consumption grows in parallel. Other new items that recently are adjusting and coming to market, by means of technology or price, are very large plasma displays, and digital video disk recordable/play components. Although these components and associated subcomponents sometimes power is derived independently, they nevertheless require the computer system to accelerate power consumption, by means of use of application software. This holds true for other independent working technologies that can be connected to the computer, such as scanners, cameras (video/audio), printers, modems, and high power audio systems. All of the above mention make the complete computer system, either directly or indirectly make use of electrical energy ever more demanding.

Computer manufactures have adapted to this change by adding fans to the computer, and with microprocessor scalability, to the microprocessor as well. Contributing to processing efficiency, the addition of fanning has made the system work up to optimal capacity. It is evident by a multitude of patents that manufactures have sought and acquire that the use of fans does work. Evidence can be seen by Table A, where a number of fan related inventions have contributed in microprocessor and system cooling. Although, utilitarian and effective in use all of these means of cooling by fanning fall short in accomplishment. Several reasons behind this claims is the bringing of room temperature air into the system. This air may be any temperature above the 78° F. (25° C.) which can only prolong an adverse effect and can work against the aim of bringing of outside air. As a coupled result of bringing outside air, the use of fans also brings in dirt and lint, which also contribute to expensive maintenance. This results in contamination of digital electronics and the mechanics of all components. Furthermore, the recirculation of air through the system does not keep all system components from the adverse effects of heat isolation. The use of fans most of the time allow the flow of air to circumnavigate only through aerodynamic pathways. Therefore manufactures have made designs that allow a better mobility of this outside air.

The design features are less popular, hence less important because the use of fans provides active heat sink, rather than passive heat sink. The design of components does work, but they are far less effective. In Table C, the patents are primarily in how their design works against the build-up of heat inside a computer system. Even though utilitarian they also fall short in completing a work aim. They also bring outside air from the room in which can be well above 78° F. (25° C.), and may contain dirt and lint. Furthermore, the use of duct type components isolates other components from getting cooled, lessening the aim of cooling the whole system. In addition, the use of cumbersome components hampers the addition of future additional adaptable devices. Although the use of feature designs helps the system cools, or eliminates the rise in temperature quite a bit, they also fall short of completing work in current and future computer systems.

In Table B, the patents are for conditioned air provided by mechanical means. The use of air conditioning is not uncommon in the markets of computers and electronic devices. The use of air conditioning is quite common for large enterprises. It is use in data centers, where strict standards must be maintain. It is also use in communication facilities where all systems must adhere to specific temperatures. Although the use of conditioned air by mechanical means is popular for large environments, small or limited areas make use of regular air conditioning. Even though air refrigeration is use evident in Table B, the patents in this table fall short of completing ample work. For most of this systems continue with the same inadequacies of the above patents. The use of outside the system air brings in contaminated air with dirt and lint, which besides heat and magnetism is dangerous to digital electronics. In addition not all computer/electronic components are conditioned by none aerodynamics design of the computer. This perpetuates heat isolation and requires spot air conditioning in targeted areas of the system, which by reason of design and economics it's impossible to compensate. Moreover the integration into a computer chassis of an air condition system complicates the work done by technicians, and can be cumbersome to diagnose a hardware problem. Additionally, the use of air conditioning in the computer requires the use of electrical energy interpedently from the power outlet.

Other engineering feats came about by designing racks and cabinets that allow the flow of air through the inside. In Table D, these features allow the movement of air from the outside environment to pass to not only one but multiple systems. The use of racks and cabinets is a popular feature of networks. The stacking of multiple thin servers, including ups, hubs, and other devices is common in creating local area networks or wide area networks. For many their needs for networking is accommodated by renting of space in a data center where professional maintenance is adequate for keeping their devices in top working conditions. Although this is through form some, it is not a fact for every user of multiple systems. Even though the patents in Table D are effective they fall short of completing a work aim. The use of recirculation outside air brings in contaminated air which contains dirt and lint and in some environments other contaminants. They also bring air which may be not acceptable for proper maintenance of these systems. Furthermore many of these systems are not design in aerodynamics in mind to begin, rather functionality of an interconnected digital environment.

In conclusion, the use of fans for recirculation of air is the most effective means of cooling a computer, specifically a microprocessor; it is by no means the best way in keeping a computational device in optimal peak performance. Although the use of conditioned air by mechanical means brings very helpful aid, in maintenances and performance, the use of interdependent systems brings new problems and complicates a technician's job. The use of special designs whether inside or outside the system, do work in preventing heat accumulation, they nevertheless hamper other components from being added, complicates a technicians work, and reiterates the same problems mentioned above.

TABLE A
US Patents with use of fan as primary cooling

| | | | | |
|---|---|---|---|---|
| 6,031,717 | 6,409,475 | 6,034,870 | 6,163,453 | 5,793,610 |
| 5,813,243 | 5,186,605 | 6,061,237 | 5,890,959 | 6,256,197 |
| 6,005,770 | 5,208,730 | 6,587,335 | 5,195,576 | 6,434,245 |
| 6,115,250 | 6,430,041 | 6,021,042 | 6,040,981 | 4,643,245 |
| 6,038,128 | 4,644,443 | 6,031,719 | 5,687,079 | 5,745,041 |

TABLE B
US Patent with use of refrigerant as primary coolant

| | | | |
|---|---|---|---|
| 4,434,625 | 5,706,668 | 4,512,161 | 3,559,728 |
| 5,587,880 | 6,493,223 | 4,526,011 | 4,546,619 |

TABLE C
US Patent with design as attribution cooling
6,282,089

TABLE D
US Patent with cabinet as main contributor to cooling

| | |
|---|---|
| 6,462,944 | 5,107,398 |

### SUMMARY OF THE INVENTION

The invention relates to a computer cooler. It is an independent working system for a computer/electronic device. It provides apart from heat dissipation other advantages that encompass the computer/electronic device medium. What the invention is a cubical air condition by mechanical means. The aim of the invention is to condition the air within in order to dissipate heat from the working computer, and to optimize the computational efficiency of the software/hardware by providing a cool or cold environment for the computational system. Although the target of the invention is to provide utilitarian alternatives, it also provides economic advantages which are also a very important in local and wide area networks.

An advantage the invention provides is the cooling of a computer. It does this work by permitting the user to slide a computer into space provided in the middle. As a computer is inserted and propriety connected, the front door is close in order to provide enclosure. This process provides an enclose environment and encapsulates the system. The encapsulation permits the proper conditioning of the air circulation providing a cool or user permitting a very cold environment. Obviously a cool (65° F. to 78° F.) environment is suitable for a regular desktop system, a cold (−15° F. to 64° F.) environment is user dependent is the decision of the user, whether using a workstation, or pushing the limits of the computational system.

A further advantage the invention provides by linear cooling is the promotion of the overall efficiency. Since computers nowadays are composed of several components apart from the processor, they require dependent components to work in optimal efficiency. A computer can only work to limit designed by software/hardware making it have a capacity of work. Even though the processor is the workhouse and powerhouse of the overall system, the complete computer is as fast as its weakest link. Thereby a deficient by means of heat accumulation component will slow down the whole system. The advantage the linear cooling provides is the overall efficiency of the whole system, by providing very cool or cold air through the system. This eliminates heat isolation spots within the computer. Although the linear cooling enclose system promotes system overall efficiency it as well provides a sterile environment.

A further advantage the computer cooler provides by encapsulation is a quasi sterile aerial environment. By keeping the whole system enclose from room or the outside air; it eliminates the movement of particulates within the digital electronics. This eliminates dirt, lint and other harmful contaminants. In the world of digital electronics dirt and contaminants are harmful to the working of the subcomponents, especially in microscopic circuits. This quasi sterile environment promotes proper digital flow, optimal component efficiency and promotion of mean time before failure (MTBF) of component systems. The enclose environment reduces maintenance time devoted to a computer, or in the case of using the computer cooler in a wide body designed, a server or network.

An additional advantage the computer cooler provides is the cooling of electronic devices link to computers, or/and electrical devices. Apart from cooling network servers, NAS, switches, MUX's . . . a wide body computer cooler can effectively keep cool electrical systems, in communications, utilities, energy and infinite locations. This further perpetuates the use of the computer cooler to desktops, workstations, and networks.

Furthermore additional advantages the computer cooler provides is the elimination of spot cooling, forcing of building air conditioners, and alternative to data centers. Besides the above advantages, economic considerations are part of decision makers. Spot cooling is the use of portable air conditioning units that reduce heat isolation in small and large rooms. As an alternative to spot cooling of workstations or servers, the computer cooler reduces the need of spot cooling. For small networks or working environments where a room in a building is intentionally kept cold, the computer cooler eliminates the need of this operation.

By conditioning the air by mechanical means in an enclose environment, the need for overall air conditioning is eliminated. This process is popular in small offices, and business of 500 people or less. An additional advantage is the use of multiple wide body computer coolers as alternative to renting/licensing data center space. The mention economic advantages are only tangible and are only considerable to a decision maker.

### DESCRIPTION OF THE PREFERRED EMBODIMENT

The present invention is intended for use with personal computers, although alternative embodiments express other ways. The following description is the detailed specification of the whole computer cooler as intended by the inventor. The specific points that compromise the design in FIG. 1 is the (1) back panel that serves as back cover and insulator, it is kept firm positioning by a number of (2) screws. Other (2) screws are use in the (1) back panel in keeping the (3) evaporator exhaust and the (4) evaporator inlet in firm position with the (1) back panel. The (5) wiring enclosure does not contain screw; rather it is for the use of wiring. The only electrical connection the (1) back panel contains is the (6) power connection. At the lower end of the figure two (7) wheels are shown in the case for this computer cooler figure. FIG. 1a is a (8) connection panel with (9) insulation contains (10) multiple connections which are for use if not using a (5) wiring enclosure and keeping the computer cooler hermetically sealed.

FIG. 2 illustrates a back side of the computer cooler middle section. FIG. 2 contains a multitude of (18) openings for screw insertion. Viewable in the figure is the (9) insulation which is very important in the middle section a (19) metal hinge is part of the middle section in the middle section (20) empty space completes the figure. FIG. 4 illustrates a front side of the computer cooler middle section. FIG. 4 contains a multitude of (22) openings for screw insertion. Viewable in the figure is the (9) insulation which is very important in the middle section, a (21) metal hinge is part of the middle section, in the middle section (20) empty space completes the figure.

FIG. 3 illustrates a top view of the computer cooler. At the back end is the (1) back panel, it is attached to the (11) refrigeration panel. At the computer cooler sides the illustration shows proper (9) insulation. A cut away view a computer tower is shown, at the lower left side a (54) thermometer and (17) readout are above the (13) frontal panel which contains an (12) intersection in the middle the (13) frontal panel retains a (14) lever for a (15) glass which acts as frontal door with a (16) push button metal knob which is use to open and close the door.

FIG. 5 is a cutaway view of the top side panel with a dock computer tower illustrating a computer tower inside. FIG. 5 illustrates the (1) back panel with the incoming air through the (11) refrigeration panel. At the computer cooler sides the illustration shows proper (9) insulation. A cut away view a computer tower is shown with (13) frontal panel which contains an (12) intersection with a cutaway view of the middle of the (13) frontal panel retains a (14) lever for a (15) glass which acts as frontal door with a (16) push button metal knob which is use to open and close the door.

In FIG. 6, the illustration depicts the frontal section of the computer cooler. It has in fade away view multiple (2) screw connections at the lower left section a lever for a (15) glass door. The (15) glass door has at its right two (28) metal clips and a (16) push button metal knob. For FIG. 6, starting form top to bottom the (13) frontal panel, with an (12) intersection with a (23) bolt screwed in-between and a (24) magnetic SPST latch. In-between is the (27) frontal opening, use for sliding a computer in-between. At the lower section in-between the (12) intersection, and the (9) insulation is another (23) bolt screwed in. Moving backward up is the (14) lever for a (15) glass at the upper left is a (2) screw intersection. At the end upward of the (15) glass is the (16) push button metal knob, it is a single push single through mechanism, meaning with one push it opens and with one push it closes. At the right is the (25) frontal clip on, with a (26) frontal opening. In FIG. 6a, the illustration shows a side view with its (9) insulation with (27) material opening, this is a plastic use in keeping insulating material from falling off. At its middle view, FIG. 7 illustrates the (14) lever for a (15) glass with its two (28) metal clips, and a (16) push button metal knob.

In FIG. 8, illustrates the thermal transfer unit (29) ac panel. Starting at the top, it contains numerous holes, these are (18) openings for screw insertion, they are located all around the (29) ac panel they are for interlocking the (1) back panel and the computer cooler middle section. The (29) ac panel contains, other openings, at the lower right section it has the (53) wiring opening at the left of it is the (30) evaporator air outlet, and at the top it has the (31) evaporator air inlet. Their contribution to the (29) ac panel is the ample flow of air within the computer cooler. Together they work in junction with the actual air conditioner, which is compose of the (39) switch use for switching the air conditioner on and off. It turns the system on the electrical distribution. It turns on the (37) compressor which compresses refrigerant and passes it throughout the system, making the refrigerant pass through the (32) condenser the (33) capillary valve the (34) capillary line (35) evaporator to the (36) line to compressor the (37) compressor and back to the (32) condenser by way of the (38) compressor to condenser line. All the electrical energy is powered by the (37a) electrical distributor. FIG. 10, is the same as FIG. 8, the only difference is the superimposition of a (40) evaporator duct with (40b) air inlet and a (40a) air outlet. The (40) evaporator duct is for proper air flow outside the computer cooler. FIG. 9, is the same as FIG. 8, but in this case the (41) condensing duct, is superimposed. The (41) condensing duct, has (41a) air inlet and (41b) air outlet. The (41) condensing duct is for the proper flow of air circulation inside the computer cooler in the (20) empty space.

FIG. 11, is an exploded sided view of the (1) back panel (9) with insulation and the air conditioning section. Starting at the upper left section in the (1) back panel segment is a (23) bolt and a (23a) bolt stud below them is a (49) air outlet grill. Further below is a (48) air inlet grill it is for letting air pass through the (47) air inlet opening and into (40a) air inlet and through the (41) condensing duct out through the (41b) air outlet. The air that passes will eventually pass then to a (32) condenser by force of the (50) condenser fan through the (51) outlet flange and out to ambience. At the right the air conditioning section, which is the heart of the computer cooler, is the (11) refrigeration panel it has a (43a) air inlet opening, where the (41) condensing duct is connected, which permits air to flow through the (41a) air inlet and out of the (41b) air outlet. The flow of air will pass through the (42) evaporator fan then the (35) evaporator then the (43b) evaporator outlet and eventually to (20) empty space, inside the middle of the computer cooler. In the middle section of the (11) refrigeration panel lies the (37) compressor. It has in proximity the (39) electrical switch below is the (52) thermometer. The (37) compressor is attached to the (11) refrigeration panel, by way of the (44) retainer together with (23) bolt and (23c) nut. With all compressors alike this (37) compressor has a (37a) compressor electrical box, a (45) connection to condenser and (46) connection to evaporator.

In conclusion to the detailed description, other figures further contemplate details. In FIG. 12, the (41) evaporator is shown in frontal position, with its (41a) air inlet and its (41b) air outlet. At the right the figure is a right angle view of the (41) evaporator with its (41a) air inlet and its (41b) air outlet. In FIG. 13, the (40) condenser is also shown, at the left in left angle view with its (40b) air inlet and (40a) air outlet. At the right a frontal position is given with the (40b) air inlet and the (40a) air outlet shown. In conclusion, a linear (FIG. 14) graph depicts logarithmic growth in electrical consumption, past present and probable future.

### BRIEF DESCRIPTION OF THE DRAWINGS

FIG. 1 is a plan view of the back side panel;

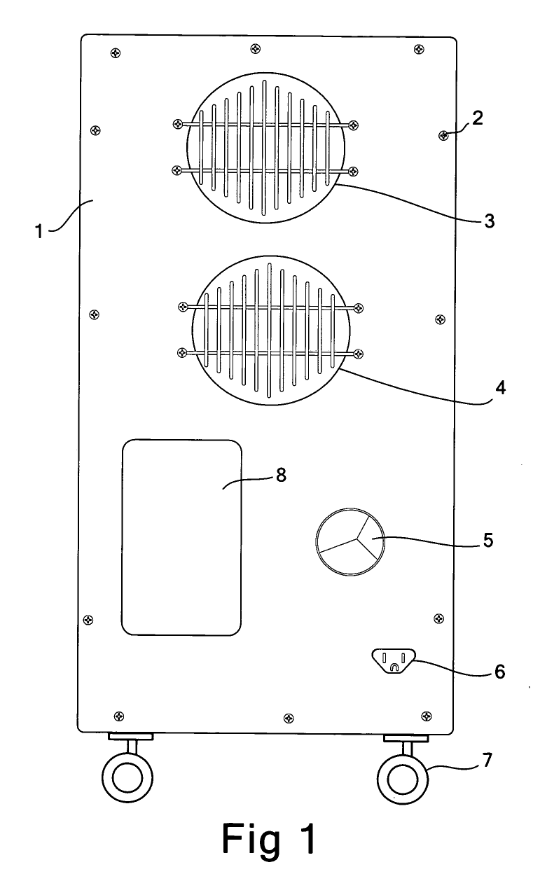

FIG. 1a is a side view of a electrical connection panel;

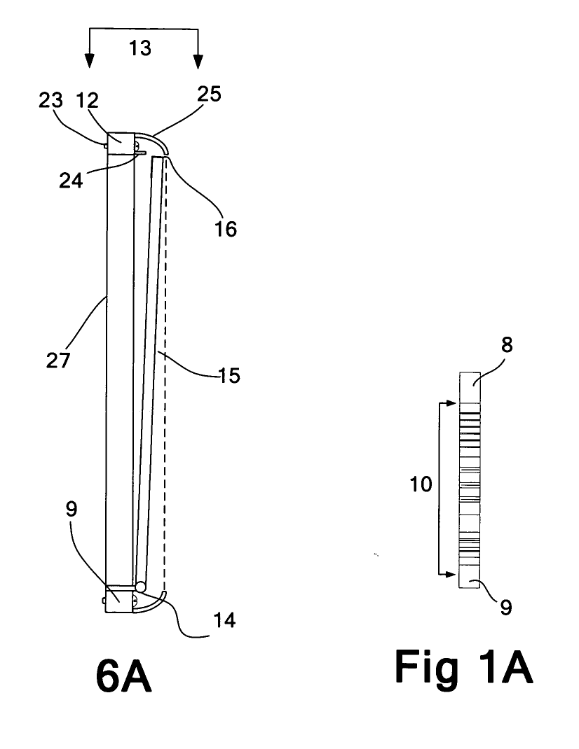

FIG. 2 is a plan view of the back side of the middle section;

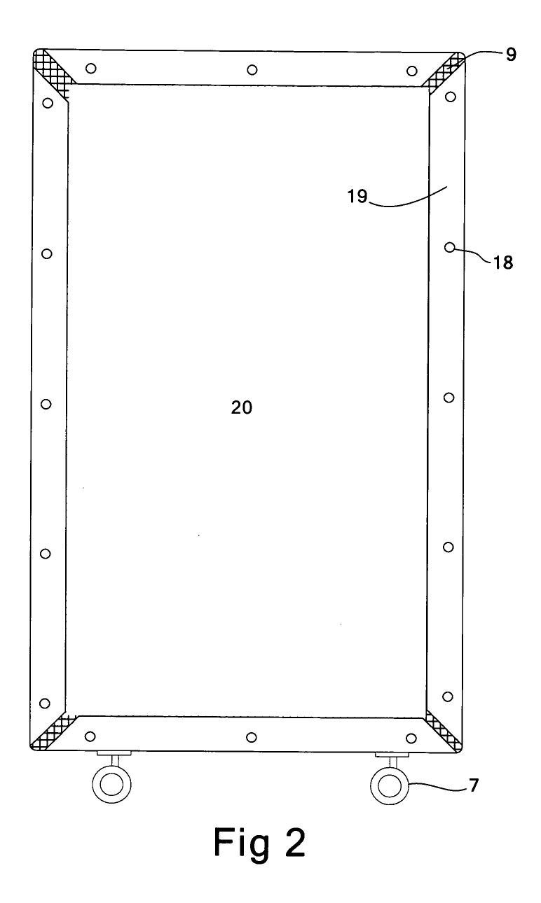

FIG. 3 is a plan view of the top side;

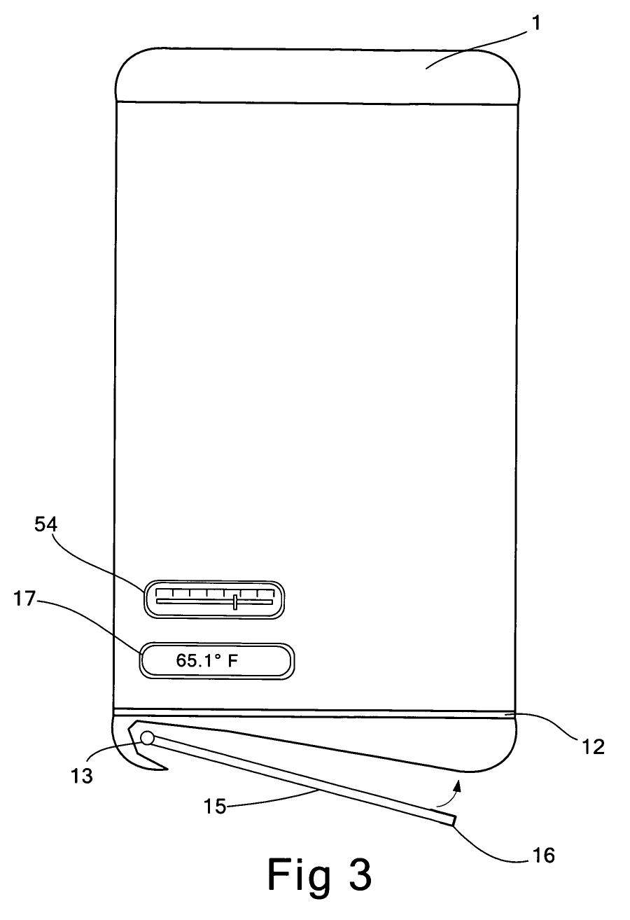

FIG. 4 is a front side view of the middle section;

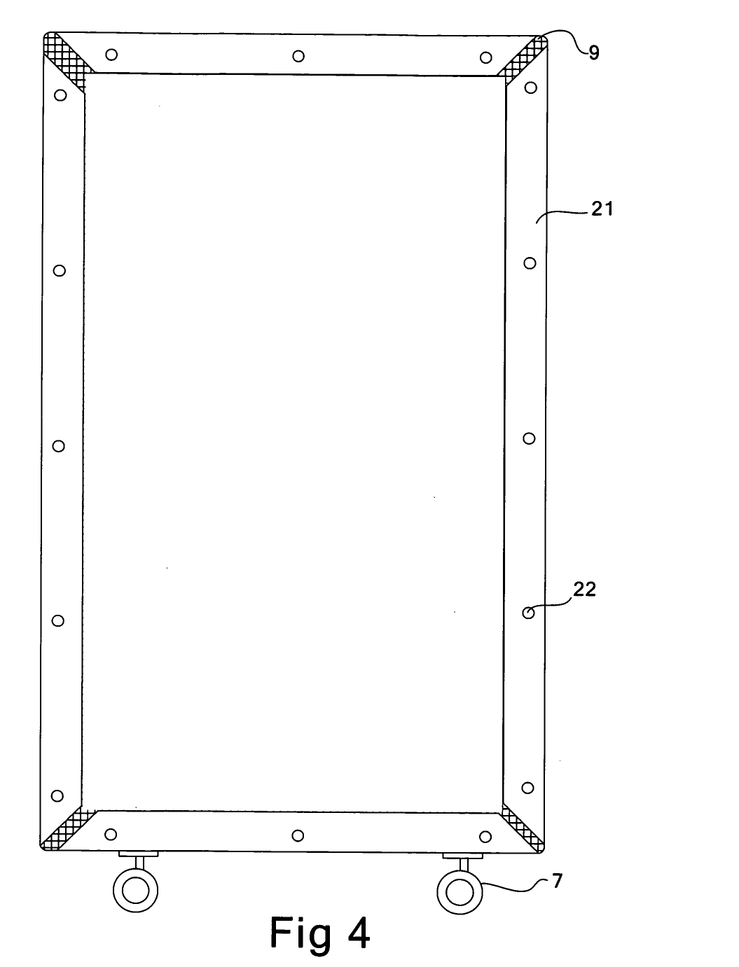

FIG. 5 is a cutaway view of the top side panel with a dock computer tower;

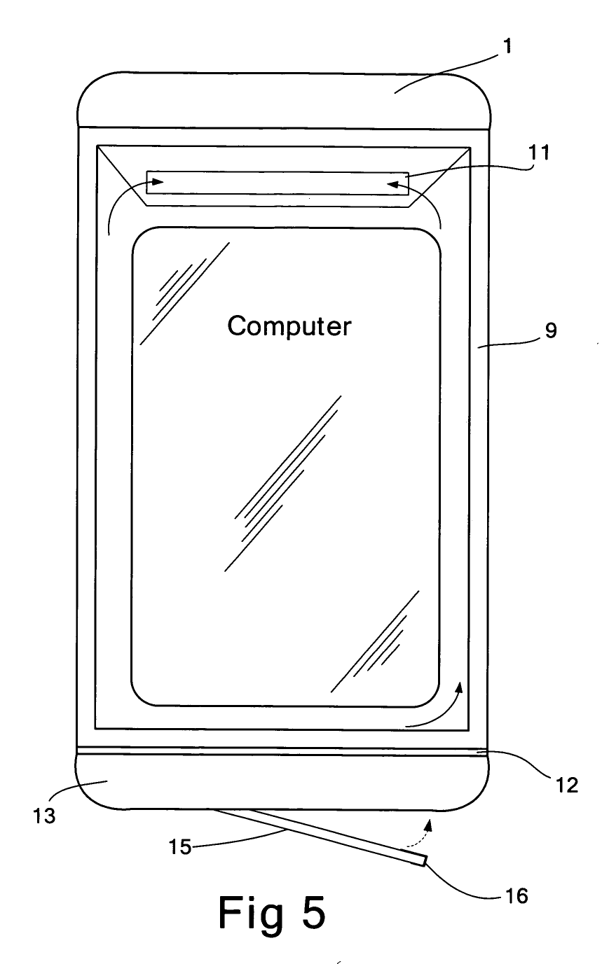

FIG. 6 is a plan front view with door closed;

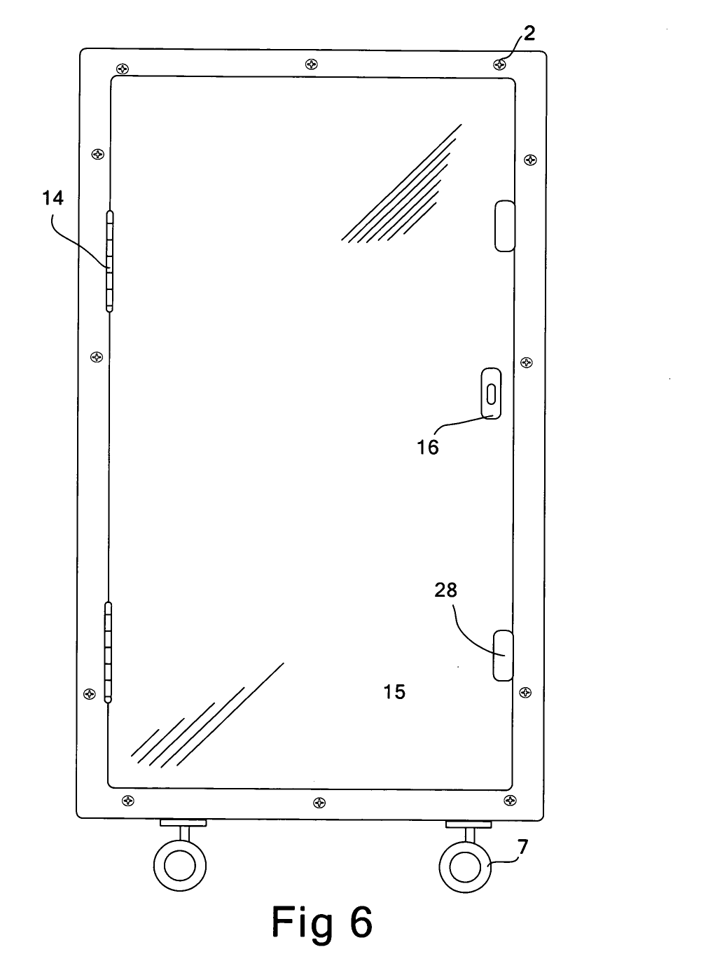

FIG. 6a is a plan top—front section view with open door;

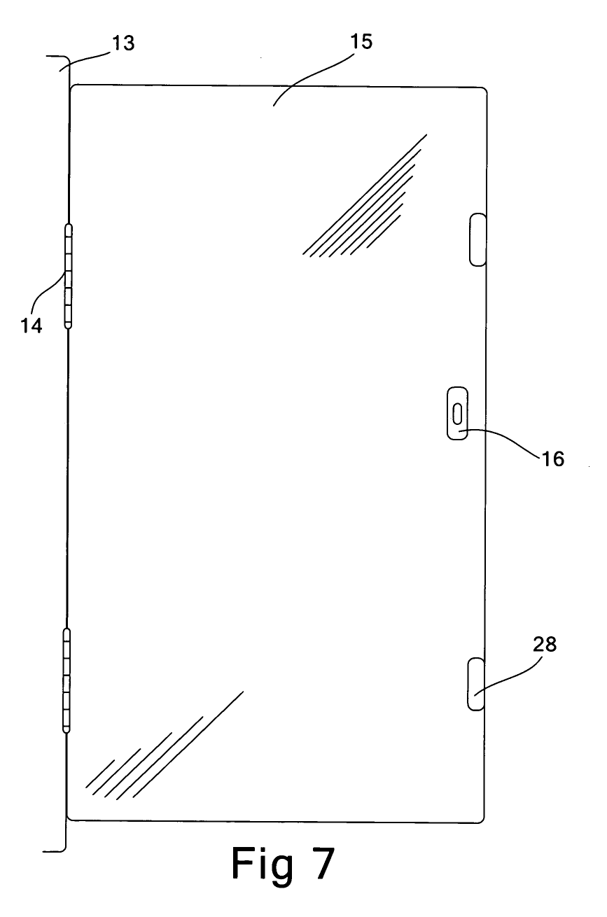

FIG. 7 is a front view of the door with magnetic hinge;

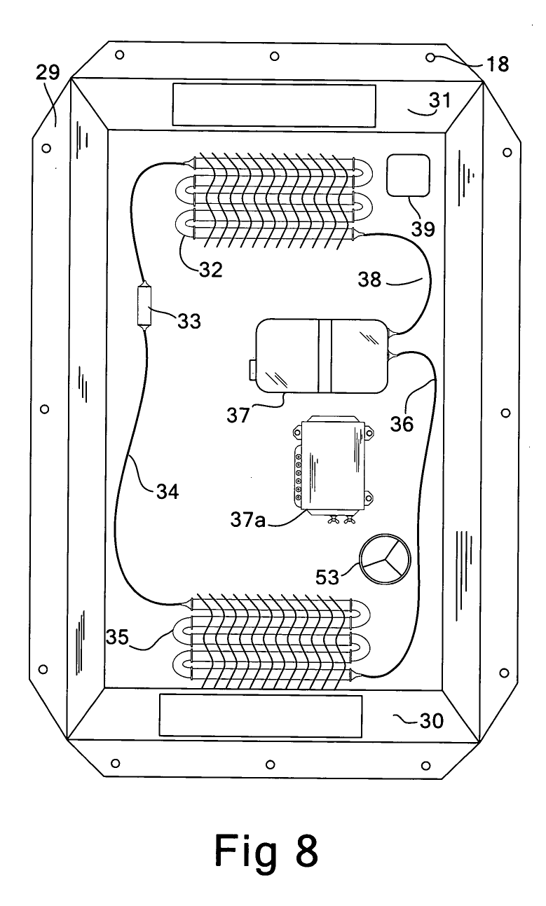

FIG. 8 is a plan view of the thermal transfer unit;

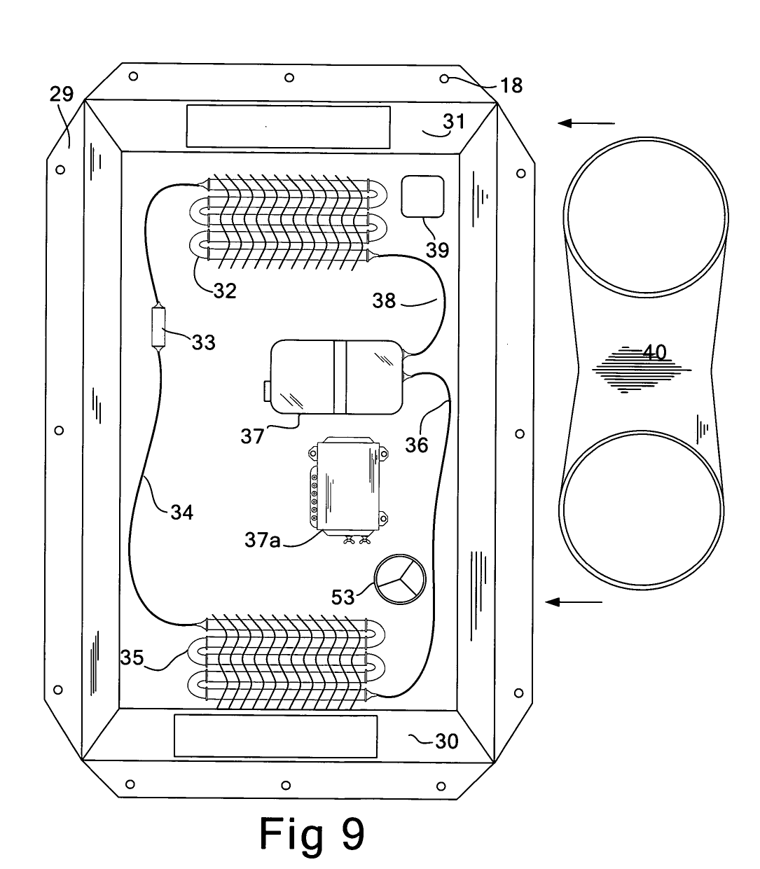

FIG. 9 is a plan view of the thermal transfer unit with condenser a duct;

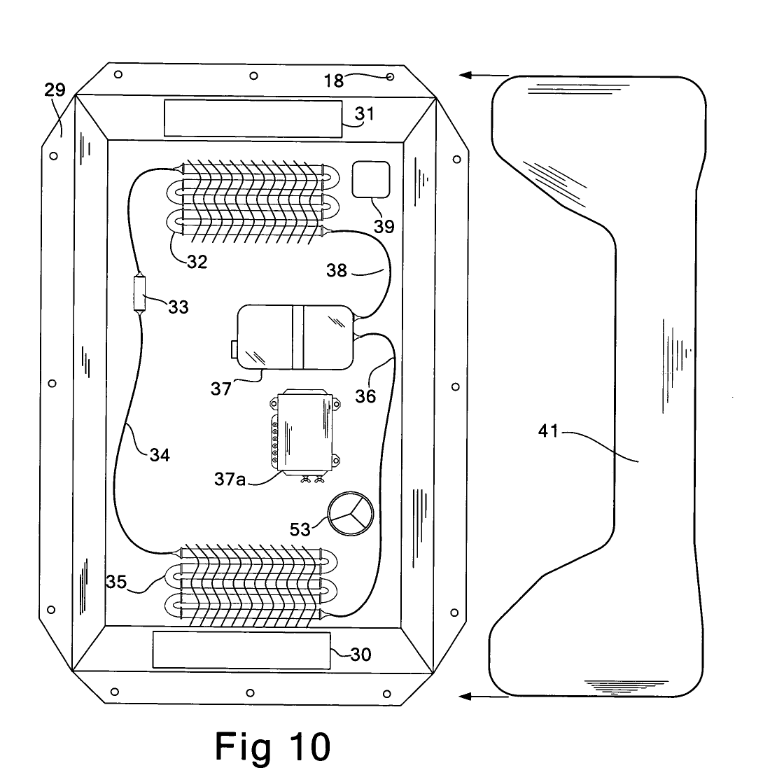

FIG. 10 is a plan view of the thermal transfer unit with evaporator a duct;

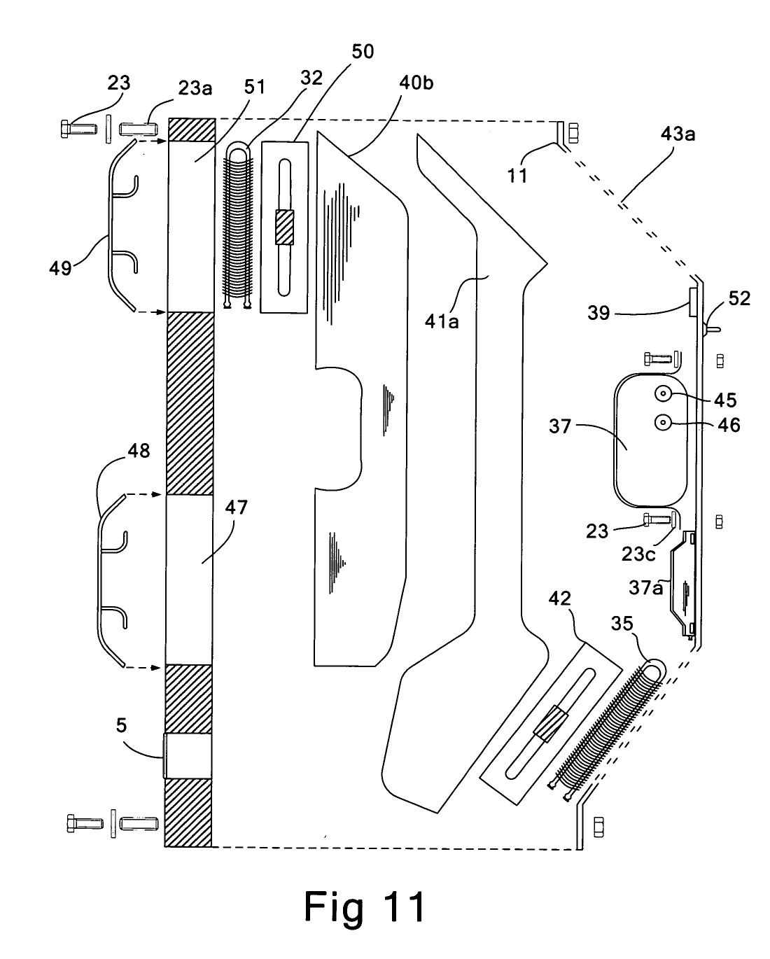

FIG. 11 is a exploded sectional view of the thermal transfer unit;

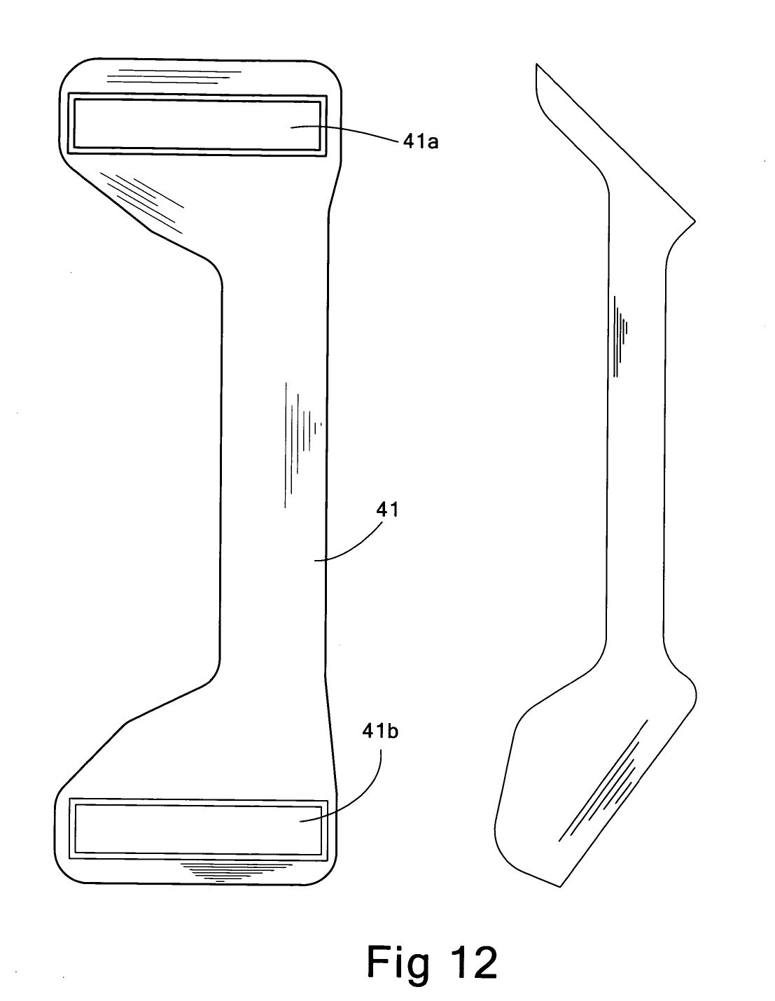

FIG. 12 is plan two sides view of the evaporator duct;

FIG. 13 is a plan two sides view of the condenser duct; and

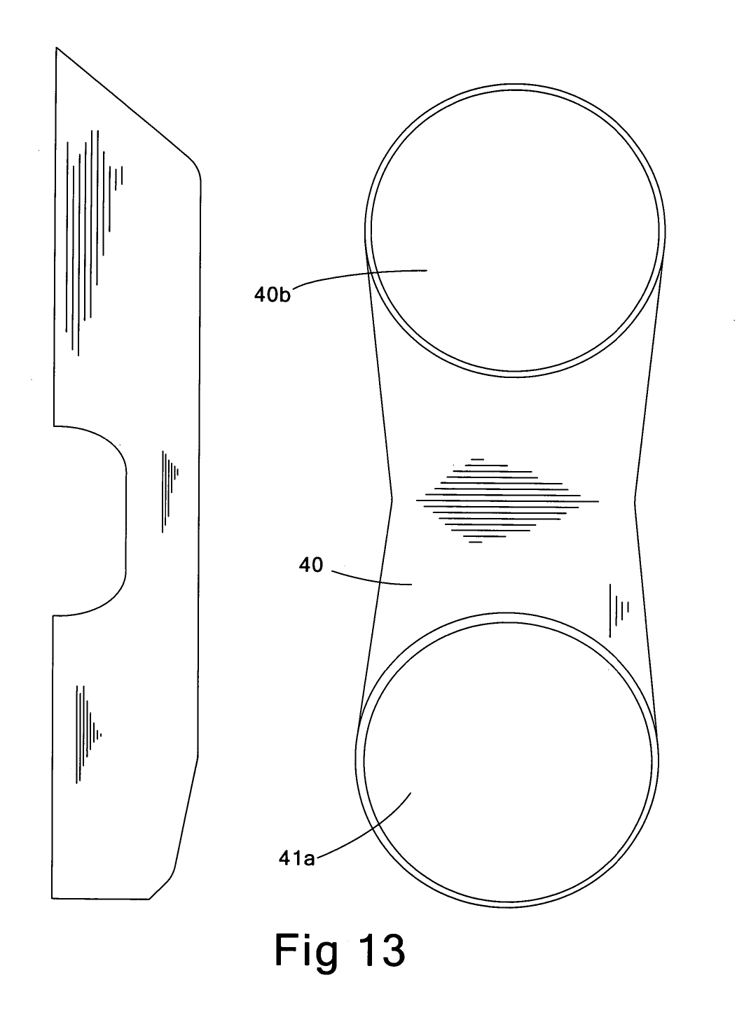

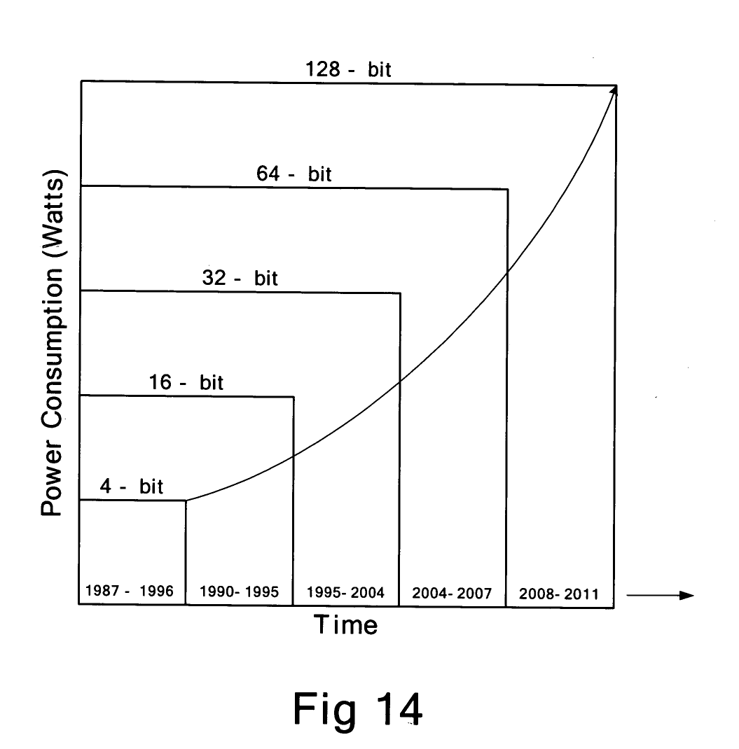

FIG. 12 is a diagram of a logarithmic example of electrical energy consumption.

1. A heat dissipation device that provides complete heat dissipation to all components in a computational system. Provides high efficiency of all working components of the computer system, and adaptable components, ensuring the optimal work produce up to its limit and engineering standards;

2. A heat dissipation device according to claim 1, which provides heat dissipation in addition to but not limited to a processor;

3. A heat dissipation device according to claim 1, which provides heat dissipation in addition to but not limited to a motherboard;

4. A heat dissipation device according to claim 1, which provides heat dissipation in addition to but not limited to random access memory;

5. A heat dissipation device according to claim 1, which provides heat dissipation in addition to but not limited to a power supply;

6. A heat dissipation device according to claim 1, which provides heat dissipation in addition to but not limited to a floppy disk drive;

7. A heat dissipation device according to claim 1, which provides heat dissipation in addition to but not limited to an optical reading/writing drives;

8. A heat dissipation device according to claim 1, which provides heat dissipation in addition to but not limited to a video cards;

9. A heat dissipation device according to claim 1, which provides heat dissipation in addition to but not limited to an audio card;

10. A heat dissipation device according to claim 1, which provides heat dissipation in addition to but not limited to system adaptable components;

11. A heat dissipation device that provides complete heat dissipation to all components in a computational system. Provides a sterile working computational environment by means of thermal heat extraction in a system enclose whereby keeping the computational system clean overall;

12. A heat dissipation device according to claim 11 wherein supplements the limit set by engineering specification in reducing mean time before failure of electrical components;

13. A heat dissipation device according to claim 11 wherein provides an increase in computations over regular fanning;

14. A heat dissipation device according to claim 11 wherein provides ample air temperature spectrum the cooler can keep the system in the subzero to room temperature; and

15. A heat dissipation device according to claim 11 wherein provides thermal heat extraction to multiple processors.
